(19) United States
(12) Patent Application Publication
(10) Pub. No.: US 2012/0180848 A1
(43) Pub. Date: Jul. 19, 2012

(54) Advanced hybrid photovoltaic-thermal solar collector

(76) Inventor: Nick P. Dalacu, Niagara Falls (CA)

(21) Appl. No.: 13/317,135

(22) Filed: Oct. 11, 2011

Related U.S. Application Data
(60) Provisional application No. 61/404,907, filed on Oct. 12, 2010.

(51) Int. Cl. H01L 31/058

(52) U.S. Cl. 136/248

(57) ABSTRACT

A hybrid photovoltaic/thermal solar collector which replace the apparently simple and reliable encapsulation with an flat box that protect the thin film solar modules, permit the collection of heat as well as electricity, is light, reduce degradation, improve reliability, permit replacement of faulty modules, reduce interconnection wiring.

### CROSS REFERENCES

This invention is directed toward a hybrid photovoltaic/thermal solar collector claiming the advantages described, but not limited to, in provisional patent application 61/404,907 filed on Oct. 12, 2010.

This invention is based on Nick Dalacu's work started in 2000 with new knowledge claims as stated in pre-granted patent US20040118445. This patent was abandoned when the inventor and his company, Canrom Photovoltaic Inc. went in financial difficulties as a result of negative attitude and influence at National Renewable Energy Laboratory and at First Solar. In essence, the inventor and his company have been robbed of benefits resulting from a very important discovery.

This invention uses knowledge as claimed in U.S. Pat. No. 6,201,179.

### FIELD OF THE INVENTION

This invention is directed toward a hybrid photovoltaic/thermal solar collector design that may prove to be highly advantageous for large scale application of residential solar energy.

### BACKGROUND AND RELATED ART

In 2001 the author of this patent discovered that accumulation of sodium ions under the tin oxide film in thin film solar modules built on soda-lime glass, trigger the principal degradation mechanism in such modules. The discovery became quickly basic knowledge. The principal contender for large scale application of photovoltaics is the CdTe-based, thin film modules deposited on a superstrate soda-lime glass. We refer in this invention to this type of thin film module although other solar electric device built on conductively coated soda-lime glass may present similar behaviour.

In order to protect the sensitive semiconductor structure that form the photovoltaic device and the fragile glass holder, at present, all commercial devices are built by covering up the superstrate holding glass plate with a back-up tempered glass sheet through a lamination process. The resulting sandwich is able to stand wind and hail and retard moisture ingress. However, the resulting plank is heavy and freeze-in thermal and mechanical stress in the glass and semiconductor structure. The edges of the conductively coated superstrate has to be sandblasted away and a different, hydrophobic, encapsulant, to prevent electro-corrosion, has to be used. Most importantly, in the present art, the tribocharging of the front surface of the superstrate it is not accounted for and its effect on the life time cycle of the thin film module built on soda-lime glass of is not understood or considered, The present art protective technique is reminiscent from the time when it was considered that water ingress into the CdTe film is the principal culprit for the thin film module degradation. Sealing the structure was considered the only solution.

### BRIEF DESCRIPTION OF THE DRAWINGS

Further advantages, features and details of the invention will be apparent from the following description of the preferred embodiments with the reference to the drawings, in which:

FIG. 1 illustrates a top view of the disposition of thin film solar modules 2-1 within a frame 2-2, under a transparent, resistant foil 3-4, on a large preformed, insulating foam board 3-1.

FIG. 2 illustrates a cross section towards the inlet end 2-3 of the collector and shows the stagnant air area 3-2 and the circulating air area 3-3 separated by the thin film solar modules 2-1 installed in the middle of the flat box between the transparent cover foil 3-4 and the foam insulating board 3-1.

FIG. 3 illustrates a cross section of a conventional thin film solar module in which the sensitive and fragile semiconductor structure 1-3 is laminated between 3-6 mm thick glass plates 1-1 and 1-2 with the edges of the superstrate 1-1 sandblasted to expose a un-coated area 1-4 to avoid electro-corrosion and water ingress.

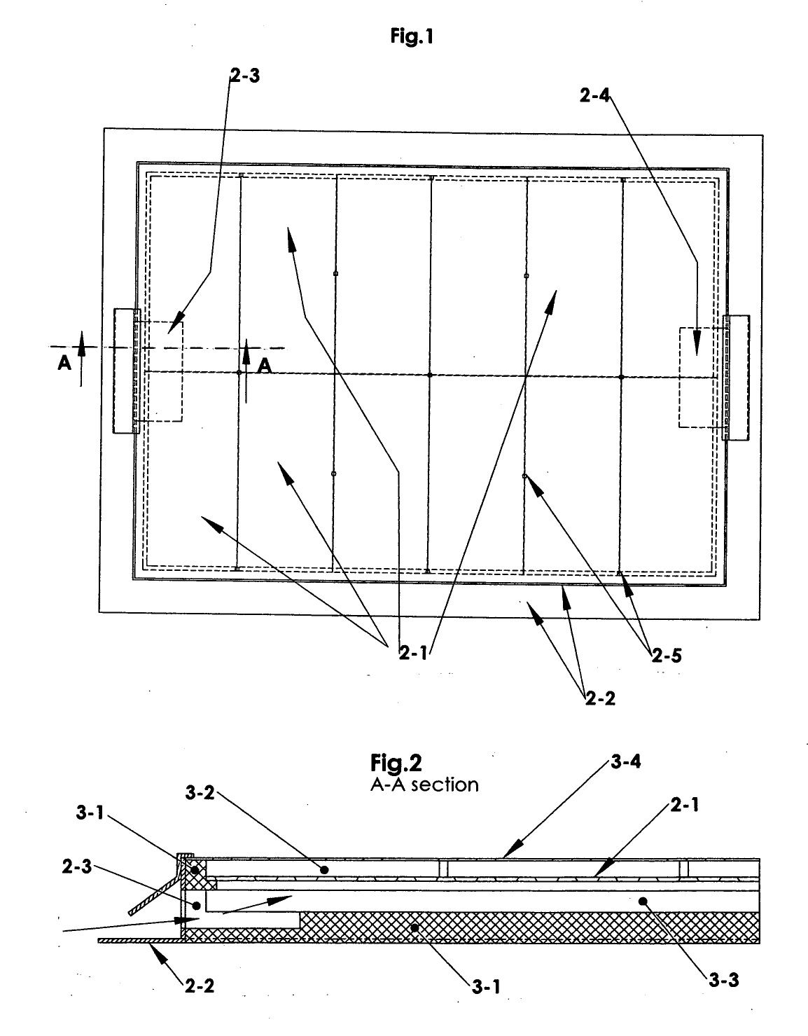

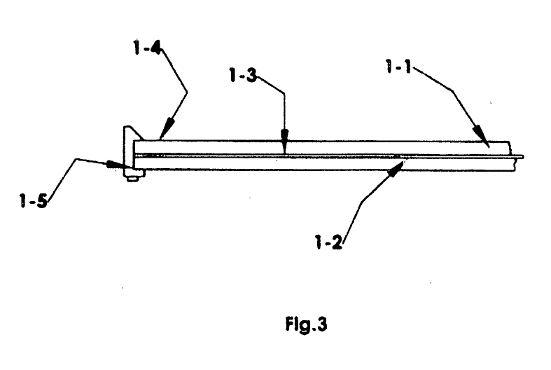

### DETAILED DESCRIPTION

As in FIG. 2 thin film solar modules 2-1 are arranged on a preformed insulating foam board 3-1 and interconnected as required through pressure contacts 2-5.

The pressure contacts 2-5 holds the modules in place. The foam board 3-1, with the thin film modules 2-1 is covered with a sturdy frame 2-2 that holds and stretch a strong transparent foil 3-4 and connect with the surrounding roofing material in a way that not allow water ingress.

As shown in FIG. 2, the thin film solar modules divides the space defined by the frame 2-2, roof and foil 3-4 into two cavities: the top stagnant air cavity 3-2 and the moving air lower cavity 3-3.

The stagnant air cavity prevent excessive heat loses through the window foil 3-4.

The lower cavity 3-3 allow air to collect heat absorbed in the solar modules 2-1, cools the solar modules 2-1 and keeps the sensitive semiconductor structure dry and clean.

The air in cavity 3-3 is brought in through inlet 2-3 from outside or re-circulated. This air is filtered by a filtering media that suppress any particulate and also improve the heat transfer. The air is pulled through outlet 2-4 and then used for space heating, evaporative cooling or in a heat storing recipient.

Even large PV-Th collectors will be assembled rapidly and relatively comfortable directly on the roof.
First the roof is prepared to integrate the collector; opening for air inlet/outlet 2-3 and 2-4 are cut and provisions for leak free installation secured.
The preformed insulating foam board 3-1 is positioned on the roof to match inlet/outlet openings 2-3 and 2-4, electrical contacts are pulled through. Sealant is used to plug openings and cracks and to attached the board 3-1 to the roof.
Thin film modules 2-1 are installed and fastened.
The electrical integrity is checked.
The cover frame 2-2 with the window foil 3-4 is installed and firmly fastened.

In prior art, a zone of sand blasted area 1-4 surrounds the semiconductor films 1-3. Heavy backup plate 1-2 has to be laminated on the solar module to stand wind, hail and water ingress. Three types sealants have to be used to prevent water ingress. The back plate 1-2 is perforated and tempered. A J-box is installed on each module and modules are interconnected with wires. The modules has to be large to reduced the contribution to cost of mounting and wiring. The damaging effects of lamination on sensitive semiconductor structure 1-3 is not alleviated. The damaging effect of tribocharging is not prevented.

1. A hybrid photovoltaic-thermal collector with a thin film heat absorber/PV generator comprising of a plurality of un-encapsulated thin film photovoltaic modules built on soda-lime glass.

2. A hybrid photovoltaic-thermal collector as in claim 1 where the thin-film photovoltaic modules are placed in the middle of a flat box and held in place, by pressure, in point like areas.

3. A hybrid photovoltaic-thermal where the holding areas as in claim 2 are also used to interconnect electrically the modules.

4. A hybrid photovoltaic-thermal collector as in claim 1 where faulty thin-film photovoltaic modules can be easily replaced.

5. A hybrid photovoltaic-thermal collector as in claim 2 where the absorber/PV generator divide the flat box in two cavities: the top cavity containing mostly stagnant air to prevent heat to escape back to “outside” and the lower cavity where air is circulated to extract heat from the absorber and to cool the PV generator.

6. A hybrid photovoltaic-thermal collector in which the arrangement as in claim 5, prevent tribocharging of the front side of the superstrate soda-lime glass and the electro-corrosion that may be associated with it. This is a significant improvement and departure from the present art.

7. The thin-film photovoltaic modules held in place as described in claim 2 are separated by thin plastic material curtains to increase the traveling path for the heat transfer agent (air) and to prevent glass to glass contact at the edge of solar module.

8. A set of plastic fibber mesh pads disposed under each module or less often to improve heat transfer and to retain dust.

9. A hybrid photovoltaic-thermal collector as in claim 1 that is so large that has to be deployed in stages as described in the specification above at page 5 line 5 to line 14 inclusive.
